(19) United States
(12) Patent Application Publication
(10) Pub. No.: US 2012/0032705 A1
(43) Pub. Date: Feb. 9, 2012

(54) Device for Detecting Pulsed Signals Comprising a Function for Detecting Tangling of Pulses

(75) Inventors: Emilie Boulanger, Saint Berthevin (FR); Frankie Letellier, Laval (FR)

(73) Assignee: THALES, Neuilly-sur-Seine (FR)

(21) Appl. No.: 12/976,928

(22) Filed: Dec. 22, 2010

(30) Foreign Application Priority Data
Dec. 23, 2009 (FR) FR0906279

(51) Int. Cl. G01R 29/00

(52) U.S. Cl. 327/2

(57) ABSTRACT

A device for detecting non-phase-modulated pulsed signals or sequences of pulses of a determined frequency includes means for detecting tangling of pulses, at least one amplifier receiving a radiofrequency signal, and restoring at least one first signal representative of the envelope of the input signal, and a second normalized signal. A phase jump estimation module includes means for estimating the phase of the radiofrequency signal, means for evaluating a phase jump, the presence of pulse tangling being detected if the phase jump is of a greater value than a determined threshold value.

### CROSS-REFERENCE TO RELATED APPLICATION

This application claims priority to foreign French patent application No. FR 0906279, filed on Dec. 23, 2009, the disclosure of which is incorporated by reference in its entirety.

### FIELD OF THE INVENTION

The present invention relates to a device for detecting pulsed signals comprising a function for detecting tangling of pulses. It can be applied more particularly to the field of secondary radar systems, notably used in systems for detecting and identifying aircraft, and more precisely detection chains used in these systems. More generally, the present invention is applied to chains for receiving pulsed signals or sequences of non-phase-modulated pulses.

### BACKGROUND

Secondary radars, commonly designated by the initials SSR corresponding to the conventional terminology “Secondary Surveillance Radar”, are widely used in the field of the detection of aerial targets. Secondary radars are typically fitted to fixed terrestrial platforms, and are often coupled to primary radars. Secondary radars can also be fitted to mobile terrestrial or aerial platforms. Secondary radars can also be designated according to the initials IFF, corresponding to the conventional terminology “Identification Friend or Foe”. IFF, initially designed for discriminating between friendly or enemy targets, has subsequently branched into a plurality of modes, used notably in civil aeronautics, for detecting aircraft fitted with transponders. The transponders fitted to the aircraft emit signals in a spontaneous manner on a periodic basis, or in response to specific interrogation signals emitted by secondary radars or interrogators. The secondary radars or interrogators pick up the signals emitted by the transponders. A specific feature of signals emitted by the transponders, termed SIF according to the acronym corresponding to the conventional terminology “Selective Identification Feature”, is that the latter take the form of non-phase-modulated pulse trains. A certain number of pulses are emitted, customarily delimited by two so-called “bracketing” pulses provided for this purpose, and commonly referred to simply as “brackets”: the absence or the presence of pulses in messages of determined duration constitutes a logical word containing certain indications specific to the aircraft, such as its identification, its altitude, etc. For example, it is possible to cite the A mode, in which the transponder of an aircraft transmits an SSR identification code, the code making it possible notably to associate, in a radar tracking system, the identification of an aircraft with a radar blip. It is also possible to cite the C mode, in which an altitude indication is added, the indication being able to for example be displayed on a control screen of an air traffic control centre, in association with the radar blip corresponding to the aircraft. In most modes considered, a transponder emits a message consisting of a sequence defined by a plurality of pulses, the pulses being emitted at an unmodulated characteristic frequency. The secondary radar detection chain then operates a decoding of the words reaching it in this form, by detecting the absence or the presence of the pulses lying between the pulses of “brackets” type, delimiting the words.

However, detection can sometimes be tricky, notably when several targets are deploying within range of the secondary radar. In such cases, pulse interleaving phenomena or indeed pulse tangling phenomena can occur. It should be noted that pulse interleaving takes place when the pulses originating from two targets are interspersed with each other, that is to say when there is no time slot of coincidence of pulses originating from the two targets, whereas tangling occurs when over at least one time period, the pulses originating from the two targets coincide. The tangling of responses can notably lead to poor decoding of the responses, and to erroneous interpretation that may have serious consequences. The incessant increase in air traffic is giving rise to an increase in cases of tangling of responses of SIF type. It is customary to use logarithmic amplifiers in secondary radar detection chains: such amplifiers make it possible notably to cover large dynamics of the input signals.

Among the technical solutions known from the prior art, there exist for example procedures consisting in utilizing the signal arising from an output of the logarithmic amplifier, termed the RSSI output or “video” output, the initials RSSI standing for the expression “Received Signal Strength Intensity” (i.e. the intensity of the power of the received signal). The RSSI output restores a signal of envelope type, representative of the reception level. The RSSI output of the logarithmic amplifier can then be linked to a high-resolution analogue-digital converter to allow digital processing of the data. Thus, there exist known procedures for detecting tangling of responses, based on the use of the envelope of the pulses. In the case where pulse tangling is detected, the response may be considered to be doubtful, and the corresponding echo may for example not be taken into account in the generation of the IFF blips, an IFF blip corresponding to the association of several IFF responses received from the same target, hence from the same code.

However, in certain cases, tangling causes only a small variation in the envelope of the signal, thus making the tangling difficult to detect. These cases arise in particular when the power levels received from various targets are similar.

Other technical solutions consist in analysing the duration of the pulses detected via the RSSI signal, based on the rising and falling edges of the signal. Abnormally long pulses may then suggest the presence of tangling phenomena. However, phenomena such as atmospheric disturbances for example, may engender a stretching of the shape of the pulses, even in the absence of tangling phenomena.

### SUMMARY OF THE INVENTION

The present invention alleviates at least the aforementioned drawbacks, by proposing a device for detecting pulsed signals comprising a function for detecting the tangling of the pulses, capable of diagnosing a tangling phenomenon even in cases where the tangling is caused by relatively similar received power levels originating from various targets, and hence making it possible to limit the number of false blips and/or of erroneous codes plotted by IFF interrogator devices.

An advantage of the invention is that it may be easily implemented in already known devices for detecting pulsed signals.

For this purpose, the subject of the invention is a device for secondary radar for detecting non-phase-modulated pulsed signals or sequences of pulses of a determined frequency comprising means for detecting tangling of pulses, at least one amplifier receiving a radiofrequency signal, and restoring at least one first signal representative of the envelope of the input signal, and a second normalized signal, wherein a phase jump estimation module comprises means for estimating the phase of the radiofrequency signal measuring the phase discrepancy between the said second normalized signal and a periodic reference signal, means for evaluating a phase jump, the presence of pulse tangling being detected if the phase jump is of a greater value than a determined threshold value.

In one embodiment of the invention, the amplifier can be a logarithmic amplifier.

In one embodiment of the invention, the means for estimating the phase of the radiofrequency signal can be implemented by a preprocessing module transposing the normalized signal into baseband, a demodulator decomposing the normalized signal into in-phase and quadrature components, the components being filtered by low-pass filters of cutoff frequencies greater than the determined frequency of the sequences of pulses, a phase estimation module then determining the value of the phase of the radiofrequency signal equal to the arc-tangent of the ratio of the quadrature and in-phase components arctan(Q/I), an analysis module detecting the presence of a phase jump.

In one embodiment of the invention, the preprocessing module, demodulator, low-pass filters, phase estimation module and analysis module can carry out digital processings, after conversion of the analogue signals by an analogue-digital converter.

In one embodiment of the invention, the analysis module can restore a signal of Boolean type representative of the presence of a pulse tangling phenomenon, when the absolute value of the difference between the values of the phase at a given sampling instant, and of the phase at the previous sampling instant, exceeds a determined threshold value.

In one embodiment of the invention, the pulse detection module can restore a signal of Boolean type of suspicion of a pulse tangling phenomenon, a response decoding module receiving the said signal of suspicion of a pulse tangling phenomenon, and the signal of Boolean type representative of the presence of a pulse tangling phenomenon arising from the analysis module, and restoring a consolidated signal of Boolean type, representative of the presence of a pulse tangling phenomenon, the said consolidated signal resulting from a logical operation of “OR” type.

In one embodiment of the invention, the detection of the presence of a phase jump, carried out by the analysis module, can be operated for a window of determined duration starting simultaneously with the start of a pulse detected by the pulse detection module.

In one embodiment of the invention, the detection of the presence of a phase jump, carried out by the analysis module, can be operated for the duration of detection of a pulse by the pulse detection module.

In one embodiment of the invention, the response decoding module can also receive a signal representative of the presence of a pulse and delivered by the pulse detection module, and undertakes the decoding of the sequences of pulses received, the response decoding module restoring at least the said consolidated signal of Boolean type, representative of the presence of a pulse tangling phenomenon, and the indications arising from the decoding of the sequences of pulses, the set of signals being applied as input to an association module discriminating the decoded indications associated with a pulse tangling phenomenon diagnosed by the response decoding module.

In one embodiment of the invention, the response decoding module can also receive a signal representative of the presence of a pulse and delivered by the pulse detection module, and undertakes the decoding of the sequences of pulses received, the response decoding module restoring at least the said consolidated signal of Boolean type, representative of the presence of a pulse tangling phenomenon, and the indications arising from the decoding of the sequences of pulses, the set of signals being applied as input to an association module ascribing to the decoded indications associated with a pulse tangling phenomenon diagnosed by the response decoding module, a confidence level greater than a determined value.

### BRIEF DESCRIPTION OF THE DRAWINGS

Other characteristics and advantages of the invention will become apparent on reading the description, given by way of example, offered with regard to the appended drawings which represent:

FIG. 1, the basic diagram of a chain for detecting pulsed signals, known from the prior art;

FIG. 2, the basic diagram of a chain for detecting pulsed signals according to an embodiment of the present invention;

FIG. 3, the basic diagram of a processing chain associated with a device for detecting pulsed signals, according to one embodiment of the invention;

FIGS. 4a and 4b, respectively a curve illustrating the temporal evolution of a signal representative of the amplitude of the signal received by a detection device, and of a signal representative of the phase of the signal received, according to one embodiment of the invention;

FIG. 5, the overall basic diagram of a device for detecting pulsed signals comprising a function for detecting tangling of pulses, according to one embodiment of the invention.

### DETAILED DESCRIPTION

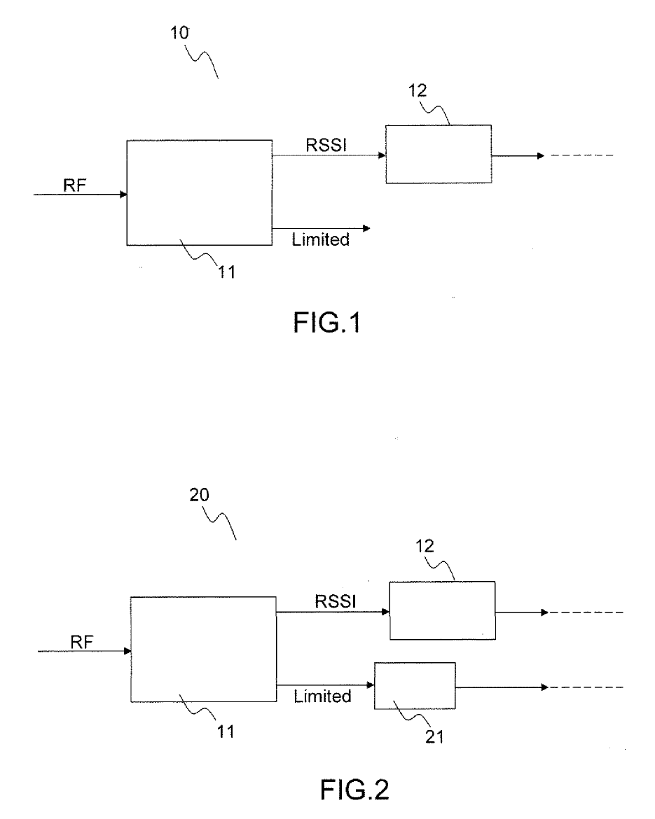

FIG. 1 presents the basic diagram of a chain for detecting pulsed signals, known from the prior art.

A detection chain 10 for detecting non-phase-modulated pulsed signals can notably comprise an amplifier 11 receiving a radiofrequency signal as input, and restoring a signal of RSSI type representative of the intensity of the signal received. A pulse detection module 12 receives the signal of RSSI type as input. The detection module can comprise filtering blocks and an analysis block, operating for example directly on analogue signals, or else implemented in a digital circuit after conversion of the analogue signals to be processed by an analogue-digital converter. The pulse detection module 12 can comprise means for analysing the shape of the pulses, able to diagnose the presence or the absence of pulse tangling phenomena. For example, the presence of a tangling phenomenon may be suspected if the amplitude of the signal corresponding to a pulse undergoes, in the course of the duration of the detected pulse, an amplitude jump greater than a determined threshold.

In a typical manner which is itself known from the prior art, the amplifier 11 may be an amplifier of logarithmic type. Logarithmic amplifiers are for example available commercially in the form of so-called COTS standard electronic hardware items, the initials standing for the expression “Commercial Off The Shelf”. The amplifier 11 can also be implemented in the form of an integrated circuit, just like the various elements of the detection chain 10. Logarithmic amplifiers usually comprise an output of RSSI type, as well as an output of the type commonly termed “limited”, restoring a normalized signal, that is to say one whose amplitude is independent of the power of the signal input to the receiver. The normalized output is customarily used when the amplifier is integrated into a chain for detecting phase-modulated signals. The normalized output is on the other hand unutilized when the logarithmic amplifier is used in a chain for detecting non-phase-modulated pulsed signals.

The principle of the present invention relies on the utilization of the signal restored by the normalized output of an amplifier of logarithmic type, so as to extract therefrom indications regarding the phase of the input signal, for example with respect to a periodic reference signal. The phase indication is then analysed so as to detect the presence of pulse tangling phenomena, or else to supplement the pulse tangling presence or absence diagnosis carried out by the pulse detection module 12, relying in a manner which is in itself known on the analysis of the power of the input signal. The analysis can for example be carried out in an analysis module, not represented in the figure, situated downstream of the pulse detection module 12.

FIG. 2 presents the basic diagram of a chain for detecting pulsed signals according to an embodiment of the present invention.

A chain for detecting pulsed signals 20 comprises for example, in a manner similar to the known detection chain described hereinabove with reference to FIG. 1, an amplifier 11 fed with the input radiofrequency signal, a pulse detection module 12 utilizing the RSSI output of the amplifier 11, of logarithmic amplifier type in the example illustrated by the figure. In the exemplary embodiment of the invention, the normalized output of the amplifier 11 is converted by an analogue-digital converter 21; of course, it is also possible not to resort to a converter, and to operate analogue processing directly on the analogue signal. Digital processing presents notably the advantage of exhibiting lower development and fine-tuning costs. The processing can for example be implemented in hardware items with a fast operating frequency, for example in programmable logic hardware, commonly denoted by the term FPGA standing for the expression “Field Programmable Gate Array”, or else in dedicated logic circuits commonly denoted by the term ASIC. Advantageously, it is possible to employ an extra filter, for example a digital filter downstream of the digital-analogue converter. This digital filter makes it possible to decrease the width of the passband, required notably to ensure the detection of the rising edges of the pulses.

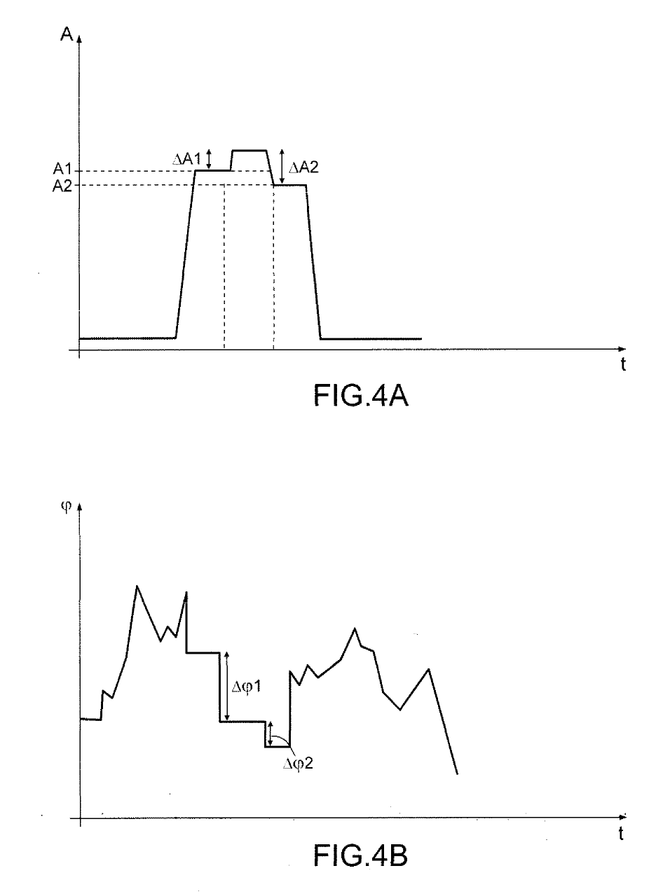

The present invention proposes to utilize the signal of the normalized output of the amplifier 11, so as to extract therefrom an indication as regards the phase of the input signal. Indeed, as is described in detail hereinafter with reference to FIG. 4, in the presence of a pulse tangling phenomenon, a more or less sharp jump is visible in the phase signal.

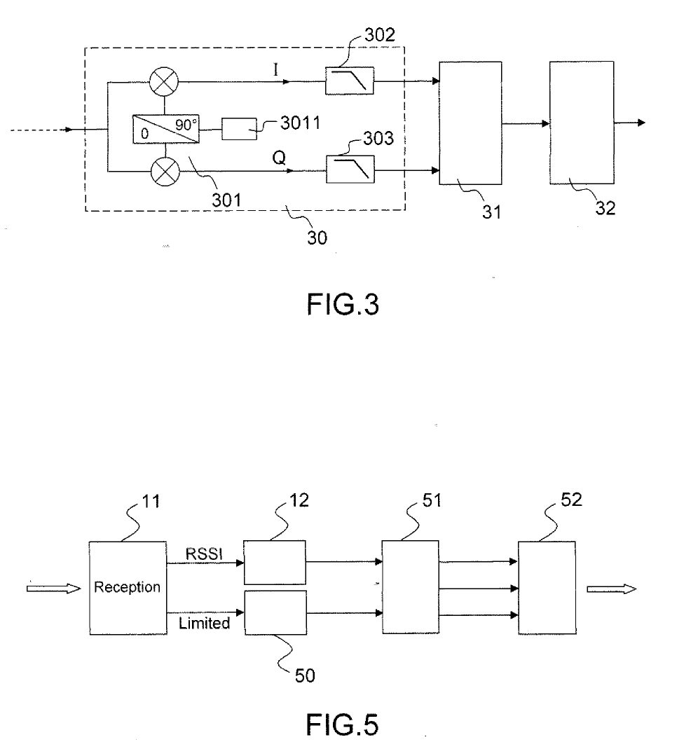

FIG. 3 presents the basic diagram of a processing chain associated with a device for detecting pulsed signals, according to one embodiment of the invention.

The signal arising from the normalized output of the amplifier 11, with reference to FIGS. 1 and 2, after possible conversion by the analogue-digital converter 21, can be fed to the input of a preprocessing module 30, followed by a phase estimation module 31, followed by an analysis module 32.

The phase estimation module 31 makes it possible to restore an indication regarding the phase of the signal arising from the normalized output of the amplifier, with respect to a reference signal. In the example illustrated by the figure, the preprocessing module 30 allows the transposition into baseband of the signal arising from the normalized output of the amplifier, by a decomposition into in-phase (I) and quadrature (Q) components, via an I/Q demodulator 301. The I/Q demodulator 301 can notably comprise, in a manner also in itself known, a local oscillator 3011 delivering a periodic reference signal. Each of the components may then be filtered by a low-pass filter 302, 303. The low-pass filters 302, 303 make it possible to preserve just the frequencies corresponding to the expected useful signals. For example, the frequency of emission by the transponders operating in one of the aforementioned modes is typically 1090 MHz. It is thus for example possible to design the low-pass filters 302, 303 in such a way that their cutoff frequency is of the order of 2 to 4 MHz. Transposition into baseband makes phase estimation easier. The filtering of the transposed signal by the low-pass filters 302, 303 also has the effect of allowing the rejection of the image spectral lines arising from the I/Q transposition.

In the example illustrated by FIG. 3, the phase estimation module 31 can for example implement a calculation of the arc-tangent of the ratio of the quadrature and in-phase components: arctan(Q/I).

Other known procedures for estimating the phase can of course also be implemented in a device according to the present invention. It is for example possible to cite the use of a delay line allowing the calculation of the scalar product of two samples of signals A and B spaced slightly apart, or else the implementation of a so-called Cordic algorithm.

FIGS. 4a and 4b present respectively a curve illustrating the temporal evolution of a signal representative of the amplitude of the signal received by a detection device, and of the phase of the signal received, according to one embodiment of the invention.

An exemplary temporal variation of a signal representative of the amplitude of the input signal is illustrated by a first curve 40 in FIG. 4a. In the example illustrated by the figure, a tangling phenomenon is caused by the presence of two pulses in the signal received. Initially, only a first pulse originating from a first target is detected, the amplitude of the signal received is substantially equal to a first value A1. Subsequently, the signal received results from the presence of two pulses originating from the first target and from a second target. Thus the amplitude of the signal received undergoes a first jump of a value AA1. Later still, the signal received results from the presence of the second pulse only, and the amplitude of the signal received undergoes a second amplitude jump AA2 and becomes substantially equal to a second value A2. Techniques for detecting tangling can for example be based on a comparison of the amplitude jump values with determined threshold values. However, in cases where the detected amplitudes A1, A2 originating from two targets are similar, and where for example the signals are in phase quadrature, the amplitude jumps A1, A2 may be very small, and thus the tangling phenomenon may not be detected. In such a case, an erroneous code may be interpreted by the IFF detection chain.

An exemplary temporal variation of a signal representative of the phase of the input signal with respect to a periodic reference signal is illustrated by a second curve 41 in FIG. 4b. In the absence of a detected pulse, the phase of the signal varies in a random manner between 0 and 2π, the signal then reflecting only a random level of noise. Initially, where only the first pulse originating from the first target is perceived, the phase takes a relatively stable value at a given phase value. Subsequently, as soon as the second pulse originating from the second target is perceived, a first phase jump occurs, of a value Δφ1. Later still, when the first pulse is no longer perceived, a second phase jump occurs, of a value Δφ2. It should be noted that the less perceptible the tangling phenomenon on the amplitude signal, the more the latter is perceptible on the phase signal. Indeed, if the amplitude of the signal resulting from the two pulsed signals is hardly substantially different from the amplitude of the signal resulting from a single of the pulsed signals, this assumes that the phase shift between these signals is substantially large. Thus, the indications provided by the amplitude and phase signals are complementary.

In one embodiment of the invention, it is for example possible to detect the presence of a pulse on the basis of the amplitude signal, and to initiate, upon the detection of a pulse, a detection time window, of a determined duration, for example of the order of 500 ns for pulses of signals of SIF type, whose width is 450 ns, or else extending over the whole of the duration of detection of the pulse. During the detection time window, an analysis of the phase signal is operated, for example via the analysis module 32 described previously in FIG. 3, so as to detect a phase jump of a value greater than a predetermined threshold value. For example, it is possible to undertake a calculation of the absolute value of the difference between the phase values, on the basis of a sample considered at an instant t, and of the previous sample, and to compare the resulting value with a threshold value.

FIG. 5 presents the overall basic diagram of a device for detecting pulsed signals comprising a function for detecting tangling of pulses, according to one embodiment of the invention.

In a schematic manner, a detection device can comprise the amplifier 11 receiving a radiofrequency signal as input, the amplifier 11 comprising notably an RSSI output feeding the pulse detection module 12, the pulse detection module 12 being able to diagnose on the basis of the RSSI signal, the presence of tangling of pulses according to a technique in itself known from the prior art, and to restore a signal representative of a suspicion of pulse tangling, this signal being able for example to be of Boolean type taking a given logic state in the presence of a suspected pulse tangling phenomenon.

The amplifier 11 also comprises a normalized output feeding a phase jump estimation module 50, comprising for example the preprocessing module 30, the phase estimation module 31, and the analysis module 32, such as were described previously with reference to FIG. 3. The phase jump estimation module 50 thus restores at its output, a signal representative of the presence of a pulse tangling phenomenon diagnosed on the basis of the phase signal, this representative signal being for example also a signal of Boolean type. The respective outputs of the pulse detection module 12 and of the phase jump estimation module 50 feed a response decoding module 51. At the output of the response decoding module 51, at least one consolidated signal representative of the presence of a pulse tangling phenomenon is restored. This signal results for example from an operation of logical “OR” type operated between the signal representative of a suspicion of pulse tangling, described previously and resulting from the analysis carried out on the RSSI signal, and the signal representative of the presence of a pulse tangling phenomenon, arising from the analysis of the phase signal.

Advantageously, the response decoding module 51 also undertakes the decoding of the sequences of pulses, by receiving as input, in addition to the signals arising from the pulse detection module 12 on the one hand and from the phase jump estimation module 50 on the other hand and representative of the presence of a pulse tangling phenomenon, a signal, restored by the pulse detection module 12, representative of the presence of a pulse. In this way, the response decoding module 51 also restores the indications resulting from the decoding of the pulses, these indications possibly being accompanied by the consolidated signal representative of the presence of a pulse tangling phenomenon, also restored by the response decoding module 51. The response decoding module 51 can also restore a Boolean signal exhibiting a determined logic state when a response has actually been detected. All these data can then for example be utilized by a radar echoes association module 52 situated downstream, the decoded indications diagnosed in the presence of a tangling phenomenon being for example discriminated, or associated with a wider confidence level.

1- A device for secondary radar for detecting non-phase-modulated pulsed signals or sequences of pulses of a determined frequency, comprising:
means for detecting tangling of pulses, at least one amplifier receiving a radiofrequency signal, and restoring at least one first signal representative of the envelope of the input signal, and a second normalized signal, wherein a phase jump estimation module comprises means for estimating the phase of the radiofrequency signal measuring the phase discrepancy between the said second normalized signal and a periodic reference signal, means for evaluating a phase jump, the presence of pulse tangling being detected if the phase jump is of a greater value than a determined threshold value.

2- A device for detecting signals according to claim 1, wherein the amplifier is a logarithmic amplifier.

3- A device for detecting signals according to claim 1, wherein the means for estimating the phase of the radiofrequency signal are implemented by a preprocessing module transposing the normalized signal into baseband, a demodulator decomposing the normalized signal into in-phase and quadrature components, the components being filtered by low-pass filters of cutoff frequencies greater than the determined frequency of the sequences of pulses, a phase estimation module then determining the value of the phase of the radiofrequency signal equal to the arc-tangent of the ratio of the quadrature and in-phase components arctan(Q/I), an analysis module detecting the presence of a phase jump.

4- A device for detecting signals according to claim 3, wherein the preprocessing module, demodulator, low-pass filters, phase estimation module and analysis module carry out digital processings, after conversion of the analogue signals by an analogue-digital converter.

5- A device for detecting signals according to claim 3, wherein the analysis module restores a signal of Boolean type representative of the presence of a pulse tangling phenomenon, when the absolute value of the difference between the values of the phase at a given sampling instant, and of the phase at the previous sampling instant, exceeds a determined threshold value.

6- A device for detecting signals according to claim 5, wherein the pulse detection module restores a signal of Boolean type of suspicion of a pulse tangling phenomenon, a response decoding module receiving the said signal of suspicion of a pulse tangling phenomenon, and the signal of Boolean type representative of the presence of a pulse tangling phenomenon arising from the analysis module, and restoring a consolidated signal of Boolean type, representative of the presence of a pulse tangling phenomenon, the said consolidated signal resulting from a logical operation of “OR” type.

7- A device for detecting signals according to claim 1, wherein the detection of the presence of a phase jump, carried out by the analysis module, is operated for a window of determined duration starting simultaneously with the start of a pulse detected by the pulse detection module.

8- A device for detecting signals according to claim 1, wherein the detection of the presence of a phase jump, carried out by the analysis module, is operated for the duration of detection of a pulse by the pulse detection module.

9- A device for detecting signals according to claim 6, wherein the response decoding module also receives a signal representative of the presence of a pulse and delivered by the pulse detection module, and undertakes the decoding of the sequences of pulses received, the response decoding module restoring at least the said consolidated signal of Boolean type, representative of the presence of a pulse tangling phenomenon, and the indications arising from the decoding of the sequences of pulses, the set of signals being applied as input to an association module discriminating the decoded indications associated with a pulse tangling phenomenon diagnosed by the response decoding module.

10- A device for detecting signals according to claim 7, wherein the response decoding module also receives a signal representative of the presence of a pulse and delivered by the pulse detection module, and undertakes the decoding of the sequences of pulses received, the response decoding module restoring at least the said consolidated signal of Boolean type, representative of the presence of a pulse tangling phenomenon, and the indications arising from the decoding of the sequences of pulses, the set of signals being applied as input to an association module discriminating the decoded indications associated with a pulse tangling phenomenon diagnosed by the response decoding module.

11- A device for detecting signals according to claim 8, wherein the response decoding module also receives a signal representative of the presence of a pulse and delivered by the pulse detection module, and undertakes the decoding of the sequences of pulses received, the response decoding module restoring at least the said consolidated signal of Boolean type, representative of the presence of a pulse tangling phenomenon, and the indications arising from the decoding of the sequences of pulses, the set of signals being applied as input to an association module discriminating the decoded indications associated with a pulse tangling phenomenon diagnosed by the response decoding module.

12- A device for detecting signals according to claim 6, wherein the response decoding module also receives a signal representative of the presence of a pulse and delivered by the pulse detection module, and undertakes the decoding of the sequences of pulses received, the response decoding module restoring at least the said consolidated signal of Boolean type, representative of the presence of a pulse tangling phenomenon, and the indications arising from the decoding of the sequences of pulses, the set of signals being applied as input to an association module ascribing to the decoded indications associated with a pulse tangling phenomenon diagnosed by the response decoding module, a confidence level greater than a determined value.

13- A device for detecting signals according to claim 7, wherein the response decoding module also receives a signal representative of the presence of a pulse and delivered by the pulse detection module, and undertakes the decoding of the sequences of pulses received, the response decoding module restoring at least the said consolidated signal of Boolean type, representative of the presence of a pulse tangling phenomenon, and the indications arising from the decoding of the sequences of pulses, the set of signals being applied as input to an association module ascribing to the decoded indications associated with a pulse tangling phenomenon diagnosed by the response decoding module, a confidence level greater than a determined value.

14- A device for detecting signals according to claim 8, wherein the response decoding module also receives a signal representative of the presence of a pulse and delivered by the pulse detection module, and undertakes the decoding of the sequences of pulses received, the response decoding module restoring at least the said consolidated signal of Boolean type, representative of the presence of a pulse tangling phenomenon, and the indications arising from the decoding of the sequences of pulses, the set of signals being applied as input to an association module ascribing to the decoded indications associated with a pulse tangling phenomenon diagnosed by the response decoding module, a confidence level greater than a determined value.
